(19) United States
(12) Patent Application Publication
(10) Pub. No.: US 2015/0091115 A1
(43) Pub. Date: Apr. 2, 2015

(54) IMAGING DEVICES WITH PARTITIONS IN PHOTOELECTRIC CONVERSION LAYER

(71) Applicant: VisEra Technologies Company Limited, Hsin-Chu City (TW)

(72) Inventors: Chi-Han LIN, Zhubei City (TW); Chih-Kung CHANG, Chu-Tung (TW); Hsin-Wei MAO, Hsinchu City (TW)

(73) Assignee: VisEra Technologies Company Limited, Hsin-Chu City (TW)

(21) Appl. No.: 14/044,816

(22) Filed: Oct. 2, 2013

(51) Int. Cl. H01L 27/146

(52) U.S. Cl. CPC H01L 27/1463; H01L 27/14629; H01L 27/14621; H01L 27/14645
USPC 257/432

(57) ABSTRACT

An imaging device is provided. The imaging device includes a substrate containing a first photodiode and a second photodiode formed thereon. A photoelectric conversion layer including a first zone and a second zone is disposed above the substrate. Further, an insulating partition is disposed between the first zone and the second zone of the photoelectric conversion layer. A first electrode is disposed under the first zone and a second electrode is disposed under the second zone of the photoelectric conversion layer. In addition, an electrical interconnection is disposed on the photoelectric conversion layer.

### BACKGROUND OF THE INVENTION

1. Field of the Invention

The invention relates to imaging devices, and more particularly, to front-side illuminated imaging devices with partitions disposed in a photoelectric conversion layer.

2. Description of the Related Art

Image sensors have been widely used in various image-capturing apparatuses, for example video cameras, digital cameras and the like. Generally, solid-state imaging devices, for example charge-coupled device (CCD) sensors or complementary metal-oxide semiconductor (CMOS) sensors, have photoelectric transducers such as photodiodes for converting light into electric charges. The photodiodes are formed on a semiconductor substrate such as a silicon chip and signal charges corresponding to photoelectrons generated in the photodiodes are obtained by a CCD-type or a CMOS-type reading circuit.

In the solid-state imaging devices, in addition to the photodiodes, a signal reading circuit and an accompanying wiring layer thereof are formed on the semiconductor substrate and above the photodiodes. Recently, the number of pixels of imaging devices has reached into the millions, such that the percentage of the area occupied by various wiring lines and electronic circuits has increased in each pixel.

As a result, the percentage of the area that can actually be utilized for the photodiodes to receive light has decreased in each pixel. This means that the luminous sensitivity of the imaging device has been reduced. In front-side illuminated imaging devices, before an incident light reaches the photodiodes, the light will be blocked by the wiring layers over the photodiodes. This causes the sensitivity of the front side illuminated imaging devices to be reduced.

### BRIEF SUMMARY OF THE INVENTION

In some imaging devices, a photoelectric conversion layer is formed on an upper side of a semiconductor substrate, which has signal reading circuits and wiring layers formed thereon, to improve the sensitivity of the imaging devices. However, the photoelectric conversion layer still has a cross-talk issue occurring in adjacent pixels of the imaging devices.

According to embodiments of the disclosure, the cross-talk issue of the photoelectric conversion layer can be overcome.

In an exemplary embodiment of the disclosure, an imaging device is provided. The imaging device comprises a substrate containing a first photodiode and a second photodiode formed thereon. A photoelectric conversion layer including a first zone and a second zone is disposed above the substrate. Furthermore, an insulating partition is disposed between the first zone and the second zone of the photoelectric conversion layer. A first electrode is disposed under the first zone and a second electrode is disposed under the second zone of the photoelectric conversion layer. In addition, an electrical interconnection is disposed on the photoelectric conversion layer.

In an exemplary embodiment of the disclosure, an imaging device is provided. The imaging device comprises a semiconductor substrate containing a plurality of photodiodes formed thereon. A photoelectric conversion layer including a plurality of zones is disposed above the semiconductor substrate. Furthermore, a plurality of insulating partitions is disposed in the photoelectric conversion layer, wherein each of the partitions is disposed between any two adjacent zones of the photoelectric conversion layer. A plurality of electrodes is disposed between the photoelectric conversion layer and the semiconductor substrate, wherein each of the electrodes individually corresponds to one zone of the photoelectric conversion layer and electrically connects to one of the photo diodes. In addition, an electrical interconnection is disposed on the photoelectric conversion layer.

In the embodiments of the disclosure, the partitions disposed between any two adjacent zones of the photoelectric conversion layer can overcome the cross-talk issue of the photoelectric conversion layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a schematic partial cross section of an imaging device according to an embodiment of the disclosure.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

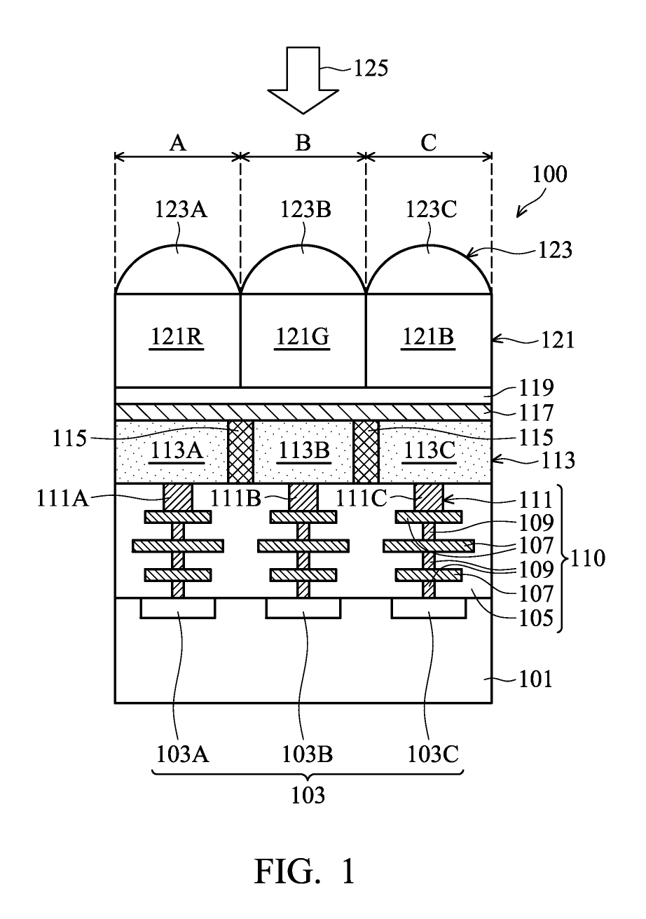

Referring to FIG. 1, a partial cross section of an imaging device 100 according to an embodiment of the disclosure is shown. The image device 100 is for example a complementary metal-oxide semiconductor (CMOS) image sensor or a charge coupled device (CCD) image sensor. The image device 100 includes a semiconductor substrate 101, and a plurality of photodiodes 103, such as the photodiodes 103A, 103B, and 103C as shown in FIG. 1, formed thereon. Each of the photodiodes 103A-103C is disposed in one respective pixel of the image device 100. For example, the photodiodes 103A, 103B, and 103C are disposed in the pixels A, B and C, respectively. Although FIG. 1 only shows three pixels, actually the image device 100 can have several million pixels or more pixels. The three pixels A, B and C as shown in FIG. 1 are for a representative portion of the image device 100.

In addition, various wiring lines and electronic circuits required for the imaging device 100 are also formed on the semiconductor substrate 101. The semiconductor substrate 101 may be a wafer or a chip. A multi-level interconnect structure 110 is formed on the semiconductor substrate 101 over the photodiodes 103. The multi-level interconnect structure 110 includes several metal layers 107 formed in several dielectric layers 105. The dielectric layers 105 can consist of several inter-layer dielectric (ILD) layers, several inter-metal dielectric (IMD) layers and a passivation layer. Furthermore, the multi-level interconnect structure 110 also includes several vias 109 formed between any two metal layers 107 and in the dielectric layers 105. Moreover, the multi-level interconnect structure 110 further includes an electrode layer 111 formed above a top metal layer 107. The electrode layer 111 consists of a plurality of electrodes, such as the electrodes 111A, 111B and 111C. The electrodes 111A, 111B and 111C are electrically connected to the photodiodes 103A, 103B, and 103C, respectively.

According to the embodiments of the disclosure, a photoelectric conversion layer 113 is formed on the multi-level interconnect structure 110 and a plurality of insulating partitions 115 is disposed in the photoelectric conversion layer 113 to divide the photoelectric conversion layer 113 into a plurality of zones, such as the zones 113A, 113B and 113C as shown in FIG. 1. The zones 113A, 113B and 113C of the photoelectric conversion layer 113 correspond to the pixels A, B and C of the image device 100, respectively.

The photoelectric conversion layer 113 can receive an incident light 125 and then generate electrons and holes in the photoelectric conversion layer 113. The amount of electrons and holes generated in the photoelectric conversion layer 113 is related to the quantity of incident light received by the photoelectric conversion layer 113. In some embodiments, the photoelectric conversion layer 113 can be formed of quantum dots. A quantum dot is a nanostructure, and typically, a semiconductor nanostructure, that confines conduction band electrons, valence band holes, or excitons (bound pairs of conduction band electrons and valence band holes) in all three spatial directions. Specifically, photons absorbed by quantum dots generate electron-hole pairs, such that the quantum dots can be used to form the photoelectric conversion layer 113. The materials of quantum dots include Group IIB-VIA quantum dots, Group IIIA-VA quantum dots, or Group IVA-VIA quantum dots. In one example, the quantum dots are formed from compound semiconductor nanocrystal cores, such as PbS and oxides of the core material, such as PbSO₃, formed on the outer surface of the core. A layer of quantum dots can be solution-coated onto the multi-level interconnect structure 110 using a spin-coating or spray coating process to form the photoelectric conversion layer 113. In some embodiments, the photoelectric conversion layer 113 can be formed of a bulk hetero structure of a P-type organic semiconductor and an N-type organic semiconductor.

According to the embodiments of the disclosure, the insulating partitions 115 disposed in the photoelectric conversion layer 113 can block the generated electrons and holes in the respective zones 113A, 113B and 113C of the photoelectric conversion layer 113. In other words, the insulating partitions 115 can prevent electric cross-talk between any two adjacent zones of the photoelectric conversion layer 113, for example, the electric cross-talk between the two zones 113A and 113B, and the electric cross-talk between the two zones 113B and 113C, etc.

In some embodiments, the material of the insulating partitions 115 can be a low dielectric-constant material having a dielectric constant lower than 0.01, which can provide better electrical isolation between any two adjacent zones of the photoelectric conversion layer 113. In one example, the material of the insulating partitions 115 having a dielectric constant lower than 0.01 is a titanium-black material. However, the materials of the insulating partitions 115 are not limited to titanium-black, and other suitable low dielectric-constant materials having a dielectric constant lower than 0.01 can also be used for the insulating partitions 115.

In some embodiments, the material of the insulating partitions 115 can be a low refractive index material having a refractive index lower than a refractive index of the photoelectric conversion layer 113, such that the insulating partitions 115 can constitute a total reflective structure for the incident light 125 entering the photoelectric conversion layer 113. The insulating partitions 115 formed of the low refractive index material can provide better optical isolation between any two adjacent zones of the photoelectric conversion layer 113. In one example, the material of the insulating partitions 115 having a refractive index lower than that of the photoelectric conversion layer 113. The material of the insulating partitions 115 can be selected from an organic low refractive index (n) material, for example poly(ethylene oxide), an organic low refractive index (n) photoresist (PR), and an inorganic low refractive index (n) material, for example a chemical vapor deposition (CVD) oxide, etc. However, the materials of the insulating partitions 115 are not limited to poly(ethylene oxide), and other suitable low refractive index materials having a refractive index lower than that of the photoelectric conversion layer 113 can also be used for the insulating partitions 115.

In some embodiments, firstly, the material of the photoelectric conversion layer 113 is blanketly deposited or coated on the multi-level interconnect structure 110. Then, the photoelectric conversion layer 113 is patterned to form spaces in the photoelectric conversion layer 113 between any two adjacent pixels of the imaging device 100, such as a space between the pixels A and B and another space between the pixels B and C, etc. Next, an insulating material is filled in the spaces of the photoelectric conversion layer 113 to form the insulating partitions 115. The photoelectric conversion layer 113 can be patterned by a photolithography process, or a printing process, or a hard mask and an etching process are used to form the spaces between the two pixels.

After the photoelectric conversion layer 113 and the insulating partitions 115 are completed, an electrical interconnection layer 117 is formed on the photoelectric conversion layer 113 and the insulating partitions 115. The electrical interconnection layer 117 is used as an upper electrode on the photoelectric conversion layer 113. The portions of the electrical interconnection layer 117 disposed on all zones of the photoelectric conversion layer 113 are electrically connected together to form a common electrode.

As shown in FIG. 1, the electrode layer 111 under the photoelectric conversion layer 113 has the electrodes 111A, 111B and 111C disposed under the zones 113A, 113B and 113C of the photoelectric conversion layer 113, respectively. Moreover, the electrodes 111A, 111B and 111C are in contact with a lower surface of the photoelectric conversion layer 113. The lower surface is opposite to an upper surface of the photoelectric conversion layer 113, wherein the incident light 125 enters the photoelectric conversion layer 113 from the upper surface. The electrode layer 111 is used as a lower electrode under the photoelectric conversion layer 113, wherein the electrodes 111A, 111B and 111C are in contact with the respective zones 113A, 113B and 113C of the photoelectric conversion layer 113. Further, the electrodes 111A, 111B and 111C are electrically connected to the respective photodiodes 103A, 103B and 103C.

A first voltage is applied to the electrical interconnection layer 117 and a second voltage is applied to the electrodes 111A, 111B and 111C, wherein the first voltage is lower than the second voltage. When the photoelectric conversion layer 113 is irradiated by the incident light 125 and then generates electron-hole pairs therein, the electrons in the zones 113A, 113B and 113C of the photoelectric conversion layer 113 are captured by the electrodes 111A, 111B and 111C, respectively. In other words, the electrical interconnection layer 117 is used as a negative electrode and the electrodes 111A, 111B and 111C of the electrode layer 111 are used as a positive electrode to help the electrons generated in the photoelectric conversion layer 113 move toward the lower electrode layer 111 and to help the holes generated in the photoelectric conversion layer 113 move toward the upper electrical interconnection layer 117. Then, the electrons captured by the electrodes 111A, 111B and 111C are conveyed to the photodiodes 103A, 103B and 103C, respectively, by passing through the multi-level interconnect structure 110.

In the embodiments of the disclosure, the photoelectric conversion layer 113 is divided into the respective zones 113A, 113B and 113C by disposition of the insulating partitions 115. The electrons generated in one electron collect zone, for example the zone 113A of the photoelectric conversion layer 113 are blocked by the insulating partition 115 from crossing to a neighboring electron collection zone, for example the zone 113B of the photoelectric conversion layer 113. Thus, a cross-talk issue between any two adjacent electron collect zones of the photoelectric conversion layer 113 is overcome by the insulating partitions 115.

In some embodiments, the photodiodes 103 can be CMOS transistors. The photodiodes 103 and the multi-level interconnect structure 110 can be fabricated on the semiconductor substrate 101 by a known semiconductor fabrication technology.

Moreover, the imaging device 100 further includes a planarization layer 119 formed on the electrical interconnection layer 117. The material of the planarization layer 119 can be an organic or an inorganic insulating material, such as epoxy resin or silicon oxide. Then, a color filter array 121 is formed on the planarization layer 119. The color filter array 121 includes a plurality of color filter portions. In some embodiments, the color filter array 121 may consist of red (R) color filter portions 121R, green (G) color filter portions 121G and blue (B) color filter portions 121B. In other embodiments, the color filter array 121 can also include white (W) color filter portions. Each of the color filter portions individually corresponds to one zone of the photoelectric conversion layer 113. For example, the color filter portions 121R, 121G and 121B correspond to the zones 113A, 113B and 113C of the photoelectric conversion layer 113, respectively.

Furthermore, a micro-lens structure 123 is disposed on the color filter array 121. The micro-lens structure 123 includes a plurality of micro-lenses 123A-123C, and each of the micro-lenses individually corresponds to one color filter portion of the color filter array 121. For example, the micro-lenses 123A, 123B and 123C correspond to the color filter portions 121R, 121G and 121B of the color filter array 121, respectively.

In some embodiments, the incident light 125 is illuminated on the front side of the semiconductor substrate 101 which has the photodiodes 103 formed thereon. In other words, the photodiodes 103 constitute a front-side illuminated image sensor 100. The incident light 125 is collected by the micro-lens structure 123, passing through the color filter array 121, the planarization layer 119, and the electrical interconnection layer 117 and then reaches the photoelectric conversion layer 113.

According to the embodiments of the disclosure, the respective zones of the photoelectric conversion layer corresponding to the pixels of the imaging device are isolated by the insulating partitions from each other. Therefore, the electrons generated in the respective zones of the photoelectric conversion layer caused by the incident light are blocked by the insulating partitions to prevent the electrons in one zone from crossing to neighboring zones of the photoelectric conversion layer. Thus, the cross-talk issue occurring in the photoelectric conversion layer without insulating partitions is overcome by the insulating partitions of the disclosure. Furthermore, the respective zones of the photoelectric conversion layer correspond to the photodiodes disposed in each pixel of the imaging device, respectively. This is beneficial for imaging devices having a small pixel size and high number of pixels.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. An imaging device, comprising:
a substrate containing a first photodiode and a second photodiode formed thereon;
a photoelectric conversion layer, including a first zone and a second zone, disposed above the substrate;
an insulating partition disposed between the first zone and the second zone of the photoelectric conversion layer;
a first electrode disposed under the first zone and a second electrode disposed under the second zone of the photoelectric conversion layer;
an electrical interconnection disposed on the photoelectric conversion layer; and
a color filter disposed above the electrical interconnection,
wherein the insulating partition is disposed in the photoelectric conversion layer and does not extend to the electrical interconnection, the color filter, and the first and second electrodes.

2. The imaging device as claimed in claim 1, wherein the material of the insulating partition comprises a low dielectric constant material having a dielectric constant lower than 0.01.

3. The imaging device as claimed in claim 2, wherein the material of the insulating partition comprises a titanium-black material.

4. The imaging device as claimed in claim 1, wherein the material of the insulating partition comprises a low refractive index material having a refractive index lower than that of the photoelectric conversion layer, and the insulating partition is a total reflective structure for an incident light entering the photoelectric conversion layer.

5. The imaging device as claimed in claim 4, wherein the low refractive index material comprises an organic low refractive index material or an inorganic low refractive index material, the organic low refractive index material comprises poly(ethylene oxide) or a photoresist, and the inorganic low refractive index material comprises a CVD oxide.

6. The imaging device as claimed in claim 1, wherein the photoelectric conversion layer has a first surface and a second surface opposite to the first surface, and an incident light enters the photoelectric conversion layer from the first surface, and the first electrode and the second electrode are in contact with the second surface of the photoelectric conversion layer.

7. The imaging device as claimed in claim 1, wherein the portions of the electrical interconnection disposed on the first zone and the second zone of the photoelectric conversion layer are electrically connected together to form a common electrode.

8. The imaging device as claimed in claim 7, wherein a first voltage is applied to the electrical interconnection and a second voltage is applied to the first electrode and the second electrode, and the first voltage is lower than the second voltage.

9. The imaging device as claimed in claim 8, wherein the photoelectric conversion layer is irradiated by an incident light to generate electron-hole pairs, and the electrons in the photoelectric conversion layer are captured by the first electrode and the second electrode.

10. The imaging device as claimed in claim 9, wherein the electrons in the first zone are blocked by the insulating partition from crossing to the second zone of the photoelectric conversion layer.

11. The imaging device as claimed in claim 9, further comprising a multi-level interconnect structure disposed between the substrate and the photoelectric conversion layer, wherein the multi-level interconnect structure comprises a plurality of metal layers, dielectric layers and inter-metal dielectric layers and a passivation layer.

12. The imaging device as claimed in claim 11, wherein the first electrode and the second electrode are disposed in the multi-level interconnect structure.

13. The imaging device as claimed in claim 11, wherein the electrons captured by the first electrode are conveyed to the first photodiode and the electrons captured by the second electrode are conveyed to the second photodiode through the multi-level interconnect structure.

14. The imaging device as claimed in claim 1, wherein the first zone of the photoelectric conversion layer corresponds to the first photodiode and the second zone of the photoelectric conversion layer corresponds to the second photodiode.

15. The imaging device as claimed in claim 1, further comprising:
a planarization layer disposed between the electrical interconnection and the color filter; and
a microlens structure disposed on the color filter.

16. An imaging device, comprising:
a semiconductor substrate containing a plurality of photodiodes formed thereon;
a photoelectric conversion layer, including a plurality of zones, disposed above the semiconductor substrate;
a plurality of insulating partitions disposed in the photoelectric conversion layer, wherein each of the partitions is disposed between any two adjacent zones of the photoelectric conversion layer;
a plurality of electrodes disposed between the photoelectric conversion layer and the semiconductor substrate, wherein each of the electrodes individually corresponds to one zone of the photoelectric conversion layer and electrically connects to one of the photodiodes;
an electrical interconnection disposed on the photoelectric conversion layer; and
a color filter array disposed over the electrical interconnection,
wherein the insulating partitions do not extend to the electrical interconnection, the color filter array and the electrodes.

17. The imaging device as claimed in claim 16, wherein the material of the insulating partitions comprises a low dielectric constant material having a dielectric constant lower than 0.01, a low refractive index material having a refractive index lower than that of the photoelectric conversion layer or a combination thereof.

18. The imaging device as claimed in claim 16, wherein electrons generated in the photoelectric conversion layer are captured by the electrodes and further conveyed to the photodiodes, and the electrons in any two adjacent zones of the photoelectric conversion layer are blocked by the insulating partition from crossing to a neighboring zone.

19. The imaging device as claimed in claim 16, wherein the portions of the electrical interconnection disposed on the plurality of zones of the photoelectric conversion layer are electrically connected together to form a common electrode, and the electrodes corresponding the plurality of zones of the photoelectric conversion layer are separated from each other.

20. The imaging device as claimed in claim 16, further comprising:
the color filter array, including a plurality of color filter portions, wherein each of the color filter portions individually corresponds to one zone of the photoelectric conversion layer;
a planarization layer disposed between the electrical interconnection and the color filter array;
a microlens structure, including a plurality of microlenses, disposed on the color filter array, wherein each of the microlenses individually corresponds to one of the color filter portions; and
a multi-level interconnect structure disposed between the semiconductor substrate and the photoelectric conversion layer, wherein the multi-level interconnect structure comprises a plurality of metal layers, dielectric layers, inter-metal dielectric layers and a passivation layer.

21. The imaging device as claimed in claim 1, wherein the material of the photoelectric conversion layer comprises quantum dots.

22. The imaging device as claimed in claim 16, wherein the material of the photoelectric conversion layer comprises quantum dots.
